(19) United States
(12) Patent Application Publication
(10) Pub. No.: US 2016/0049177 A1
(43) Pub. Date: Feb. 18, 2016

(54) MEMORY SYSTEM, STORAGE SYSTEM

(71) Applicant: Kabushiki Kaisha Toshiba, Tokyo (JP)

(72) Inventor: Masanori Shiozawa, Yokohama Kanagawa (JP)

(21) Appl. No.: 14/485,374

(22) Filed: Sep. 12, 2014

Related U.S. Application Data
(60) Provisional application No. 62/037,869, filed on Aug. 15, 2014.

(51) Int. Cl. G11C 5/14

(52) U.S. Cl. CPC G11C 5/141

(57) ABSTRACT

According to one embodiment, a memory system includes a power supply circuit. The power supply circuit includes a first capacitor circuit which applies a voltage to a nonvolatile memory and a memory controller, and a second capacitor circuit which adds a further voltage to the voltage applied by the first capacitor circuit, when the voltage applied by the first capacitor circuit is less than a set value.

### CROSS-REFERENCE TO RELATED APPLICATIONS

This application claims the benefit of U.S. Provisional Application No. 62/037,869, filed Aug. 15, 2014, the entire contents of which are incorporated herein by reference.

### FIELD

Embodiments described herein relate generally to a memory system and a storage system.

### BACKGROUND

As a storage medium, there is a solid state drive (SSD) having a nonvolatile semiconductor memory and an interface similar to that of a hard disk drive (HDD). Such solid state drives incorporate an auxiliary power supply for power loss protection (PLP).

### BRIEF DESCRIPTION OF THE DRAWINGS

FIG. 1 is a perspective view showing a storage system utilizing a memory system according to a first embodiment;

FIG. 2 is a perspective view for explaining structural elements of the memory system according to the first embodiment;

FIG. 3 is a block diagram showing the circuit structure of the memory system according to the first embodiment;

FIG. 4 is a block diagram showing an auxiliary power supply circuit according to the first embodiment;

FIG. 5 is a view showing table T1 according to the first embodiment;

FIG. 6 is a view showing table T2 according to the first embodiment;

FIG. 7 is a flowchart showing a power loss detection operation (performed upon power-on);

FIG. 8 is a flowchart showing a power loss detection operation (performed in a normal state);

FIG. 9 is a view for explaining an auxiliary power supply circuit as a comparative example;

FIG. 10 is a view showing a state (initial state) of the auxiliary power supply circuit according to the first embodiment;

FIG. 11 is a view showing a state (assumed when a predetermined time period has elapsed) of the auxiliary power supply circuit according to the first embodiment;

FIG. 12 is a graph showing the difference in the degradation characteristic of a capacitor capacitance between the first embodiment and the comparative example;

FIG. 13 is a view showing the arrangement of first and second capacitor circuits on a circuit substrate, employed in a second embodiment; and

FIG. 14 is a view for explaining an auxiliary power supply circuit according to a third embodiment.

### DETAILED DESCRIPTION

Various embodiments will be described hereinafter with reference to the accompanying drawings.

According to one embodiment, a memory system includes a nonvolatile memory; a memory controller which controls the nonvolatile memory; and an auxiliary power supply circuit which applies an auxiliary voltage for performing backup to the nonvolatile memory and the memory controller. The auxiliary power supply circuit includes: a first capacitor circuit which applies the auxiliary voltage; and a second capacitor circuit which adds a further voltage to the auxiliary voltage when the auxiliary voltage applied by the first capacitor circuit is less than a voltage needed for the backup.

In the description below, some elements are each expressed by a plurality of expressions. However, those expressions are merely examples, and other expressions may be imparted to the elements. Further, the elements, each of which is not expressed by a plurality of expressions, may be expressed by other expressions.

Further, the figures attached are schematic ones, in which the dimensional relationship between thicknesses and planar sizes, and the ratio in thickness between layers, may differ from the actual ones. Yet further, the relationships in dimension, the ratio in thickness between layers, etc., may vary between the figures.

### First Embodiment

[1. Structure]

[1-1. Storage System]

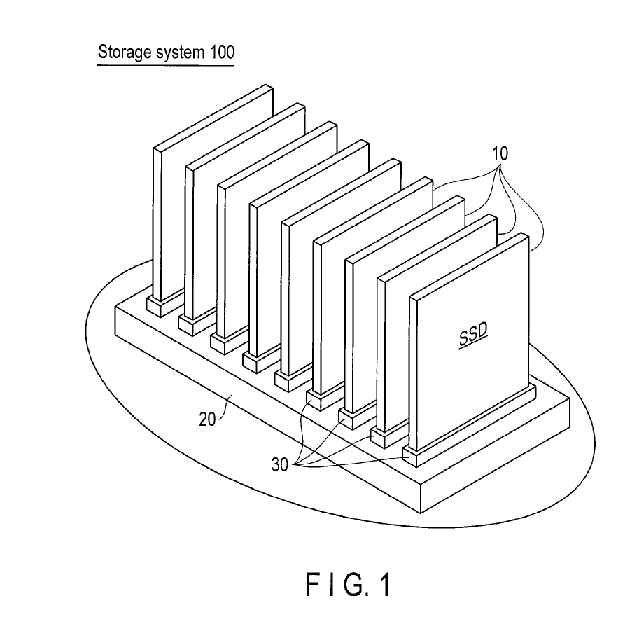

Referring first to FIG. 1, a storage system 100 incorporating a memory system 10 according to a first embodiment will be described. In this embodiment, the storage system 100 uses a plurality of solid state drives (SSD) as examples of the memory systems 10. The SSDs 10 are, for example, relatively small modules, and have an outer size of, for example, about 20 mm×30 mm. The size of the SSDs is not limited to this, but may be changed in various ways.

As shown, each SSD 10 in the first embodiment can be used, attached to a host device 20, such as a server, incorporated in, for example, a data center or a cloud computing system operated in an enterprise. Thus, each SSD 10 in the first embodiment may be an enterprise SSD (eSSD).

The host device 20 comprises a plurality of connectors (e.g., slots) 30 that, for example, open upward. Each connector 30 is, for example, a Serial Attached SCSI (SAS) connector. The SAS connector enables the host device 20 and the SSD 10 to communicate with each other at high speed utilizing a 6-Gbps dual port.

Further, the SSDs 10 are engaged with the connectors 30 of the host device 20, and are supported by them, substantially erected. This structure enables a plurality of memory systems 10 to be mounted together, which reduces the size of the host device 20. Further, each of the SSDs 10 is a small form factor of 2.5 inches. This shape is compatible with that of an enterprise HDD (eHDD), which enables each SSD to be compatible with the enterprise HDD (eHDD). The SSD 10 is not limited to an enterprise one. For instance, the SSD 10 can be used, of course, as a memory medium for a consumer electronic device, such as a notebook portable computer or a tablet terminal.

[1-2. Memory System]

The memory system 10 of the first embodiment will now be described.

[1-2-1. Structural Elements of Memory System]

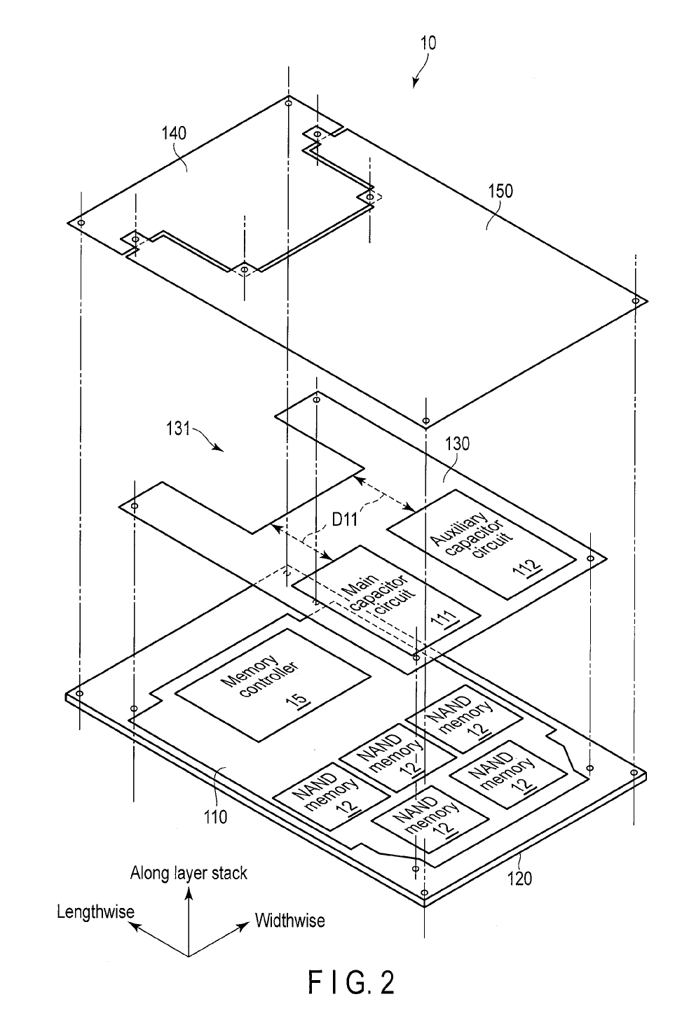

Referring first to FIG. 2, a description will be given of the structural elements of the memory system (SSD) 10 of the first embodiment. FIG. 2 schematically shows only main structural elements, and does not show the other detailed members.

As shown, the memory system (SSD) 10 of the first embodiment comprises two circuit boards 110 and 130 and two exterior members 140 and 150. The structural elements (110, 130, 140, 150) constituting the memory system 10 are screwed to form an integral structure along the thickness of the stacked structure as shown in the figure.

The peripheral and backside portions of the circuit board (first board) 110 are covered with an exterior member 120. A plurality of NAND flash memories (NAND memories) 12 and a memory controller 15 are packaged in the circuit board 110. The NAND memories 12 and the memory controller 15 will be described later in detail. The connectors 30 are provided on the peripheral portions of the circuit board 110 near the memory controller 15, although they are not shown in the figure.

A main capacitor circuit 111 and an auxiliary capacitor circuit 112 are mounted on the circuit board (second board) 130. The circuit board 130 has a predetermined opening 131 formed in an area thereof overlapping with the memory controller 15 along the thickness of the stacked structure. The main capacitor circuit 111 and the auxiliary capacitor circuit 112 are arranged on the circuit board 130 at a predetermined distance D11 from the opening 131 along the length of the SSD module 10. The main capacitor circuit 111 and the auxiliary capacitor circuit 112 will be described later in detail.

The exterior member (first exterior member) 140 is provided in a position overlapping with the memory controller 15 and the opening 131 along the thickness of the stacked structure, and is screwed to the exterior member 120 to cover the memory controller 15.

The exterior member (second exterior member) 150 is provided in a position overlapping with the circuit board 130 along the thickness of the stacked structure, and is screwed to the exterior member 120 to cover the circuit board 130. The two exterior members 140 and 150 are screwed to each other to form an integral body as shown in the figure.

As shown in the figure, the exterior members 140 and 150 have separate portions. As a result, even when the heat generated by the memory controller 15 during its operation is transferred to the exterior member 140, it is blocked by the air between the separate portions of the exterior members 140 and 150, whereby the amount of heat transferred to the exterior member 150 is reduced. By thus making the heat generated by the memory controller 15 difficult to be transferred to the main capacitor circuit 111 and the auxiliary capacitor circuit 112, degradation of the capacitance of the capacitors due to the heat described later can be reduced. Further, the exterior members 140 and 150 may be formed of different types of materials, such as metals, which have different thermal conductivities.

The main capacitor circuit 111 and the auxiliary capacitor circuit 112 are arranged on the circuit board 130 at a predetermined distance D11 from the opening 131 along the length of the SSD. Accordingly, the heat generated by the memory controller 15 is hard to transfer to the main capacitor circuit 111 and the auxiliary capacitor circuit 112, whereby degradation of the capacitors due to heat can be reduced.

[1-2-2. Circuit Structure of Memory System]

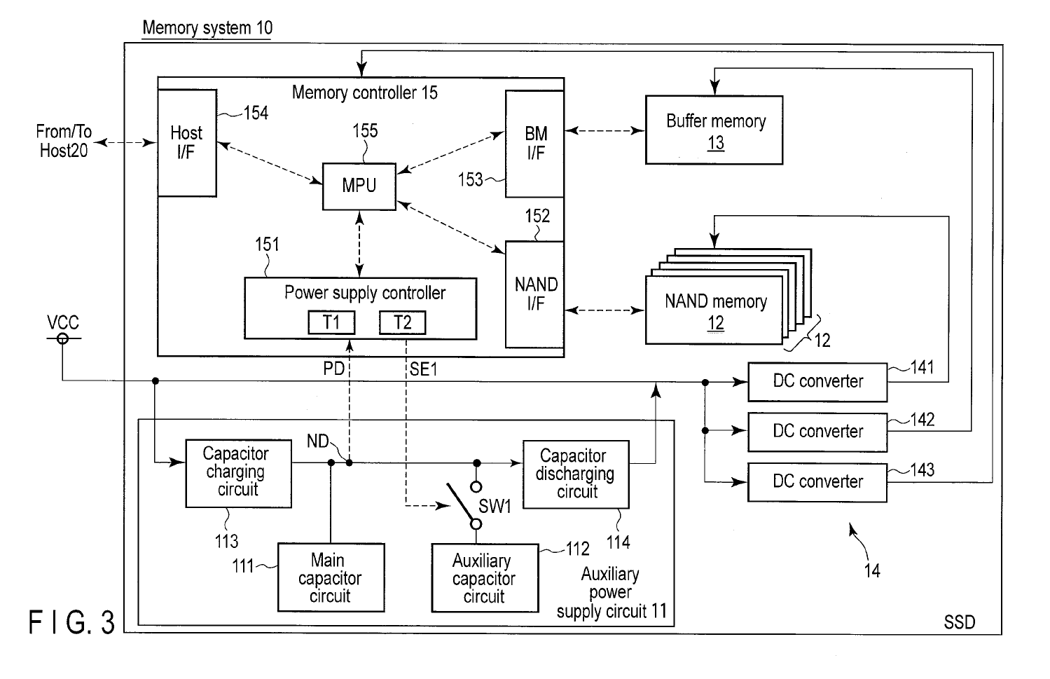

Referring then to FIG. 3, a description will be given of the memory system (SSD) 10 of the first embodiment. In FIG. 3, the arrows indicated by the broken lines are indicative of power supply voltage paths, and the arrows indicated by the solid lines are indicative of signal paths.

As shown, the memory system (SSD) 10 of the first embodiment comprises an auxiliary power supply circuit 11, NAND memories 12, a buffer memory 13, DC converters 14 and a memory controller 15.

The auxiliary power supply circuit (power supply circuit) 11 serves as an auxiliary power supply that supplies each circuit with a predetermined auxiliary power supply voltage when the memory system 10 is electrically isolated from an external power supply VCC. For instance, the auxiliary power supply circuit 11 supplies the auxiliary power supply voltage to the memory controller 15 and the NAND memory 12 to operate them when the supply of the power supply voltage from the external power supply VCC is interrupted. Using the supplied auxiliary power supply voltage, the memory controller 15 writes (copies) user data to the NAND memory 12 for user data backup or protection.

The auxiliary power supply circuit 11 supplies the memory controller 15 with a detection signal PD that is indicative of whether the auxiliary power supply voltage supplied by the auxiliary power supply circuit 11 is sufficient as a backup voltage. More specifically, the detection signal PD detects the capacitance or impedance of a node ND, described later. Based on the received detection signal PD, the memory controller 15 supplies a selection signal SE1 to the auxiliary power supply circuit 11. The auxiliary power supply circuit 11 comprises the main capacitor 111, the auxiliary capacitor 112, a switch SW1, a capacitor charging circuit 113 and a capacitor discharging circuit 114.

The main capacitor circuit 111 comprises a main capacitor (not shown), and applies the voltage, accumulated in the main capacitor as an auxiliary voltage, to the aforementioned node ND.

The auxiliary capacitor circuit 112 comprises an auxiliary capacitor (not shown), and applies the voltage accumulated in the auxiliary capacitor as an auxiliary voltage, to the aforementioned node ND in accordance with the ON/OFF state of the switch SW1.

The switch SW1 switches conduction/non-conduction states between the auxiliary capacitor circuit 112 and the node ND when it assumes ON and OFF states in accordance with a selection signal SE1 from the memory controller 15.

The capacitor charging circuit 113 has its input connected to the external power supply VCC, and its output connected to the node ND, thereby applying the power supply voltage from the external power supply VCC to the node ND.

The capacitor discharging circuit 114 has its input connected to the node ND, and its output connected to the inputs of the DC converters 14 (141-143), thereby discharging the voltage at the node ND to the inputs of the converters 14.

The NAND memories 12 are operated by an internal power supply voltage applied thereto via the DC converter 141, and comprise a plurality (in this embodiment, 5 (5 chips) as aforementioned) of nonvolatile memories. Each NAND memory 12 comprises a plurality of physical blocks that include a plurality of memory cells arranged at the intersections of word and bit lines. In the NAND memory 12, data is erased on a physical block basis. Namely, the physical block is a unit of data erasure. Data write and read are performed on a page (word line) basis in each block.

The buffer memory 13 is operated by an internal power supply voltage applied thereto via the DC converter 142, and temporarily holds predetermined data. The buffer 13 can be formed of, for example, a static random access memory (SRAM), but is not limited to it. For instance, the buffer memory 13 can also be formed of magnetoresistive random access memory (MRAM).

The DC converters 14 (141-143) applies, to each circuit (12, 13), a predetermined low voltage as an internal power supply voltage, into which the external power supply voltage VCC or a power supply voltage from the auxiliary power supply circuit 11 is converted.

The memory controller 15 is operated by an internal power supply voltage applied thereto via the DC converter 143, and controls the entire memory system 10. For instance, the memory controller 15 controls access (data write, data read, data erasure, etc.) to the NAND memories 12 in accordance with instructions (request, command) from the host device 20. The memory controller 15 comprises a power supply controller 151, a NAND I/F 152, a BM I/F 153, a host I/F 154 and a MPU 155.

Under the control of the MPU 151, the power supply controller 151 receives a detection signal PD from the auxiliary power supply circuit 11, and transmits a selection signal SE1 to the auxiliary power supply circuit 11 based on the received detection signal PD. The power supply controller 151 comprises tables T1 and T2. Tables T1 and T2 will be described later in detail. Although the power supply controller 151 is incorporated in the memory controller 15, the structure is not limited to this.

Under the control of the MPU 151, the NAND I/F (NAND interface, communication unit) 152 performs access compliant with the NAND memories 12 and the NAND I/F protocol.

Under the control of the MPU 151, the BM I/F (buffer memory interface, communication unit) 153 performs access compliant with the buffer memory 13 and the BM I/F protocol.

Under the control of the MPU 151, the host I/F (host interface, communication unit) 154 performs access compliant with the host device 20 and the host I/F protocol. For instance, the host I/F 154 accesses the host device 20 by the aforementioned SAS (Serial Attached SCSI).

The MPU (microprocessor unit, controller) 155 is, for example, a processor, and controls the entire memory controller 15.

[1-2-3. Circuit Structure of Auxiliary Power Supply Circuit]

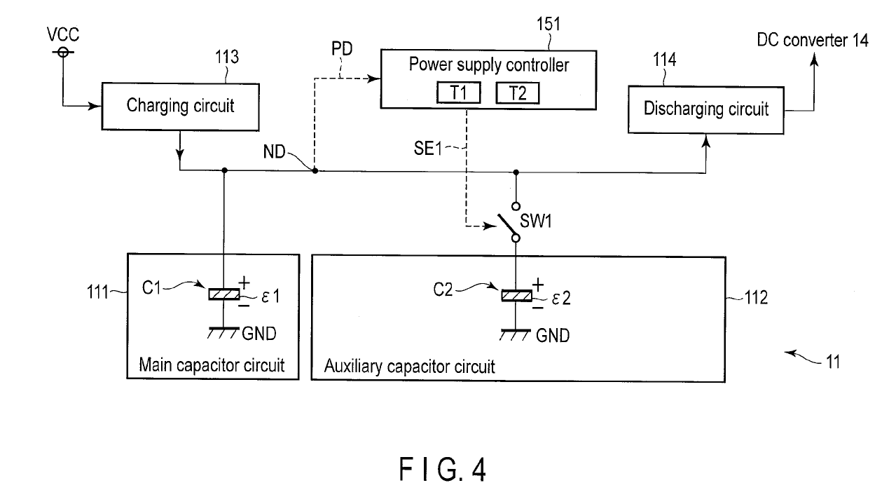

Referring then to FIG. 4, the circuit structure of the auxiliary power supply circuit 11 according to the first embodiment will be described in detail. As shown, the main capacitor circuit 111 and the auxiliary capacitor circuit 112 of the auxiliary power supply circuit 11 according to the first embodiment comprise capacitors C1 and C2, respectively. The capacitors C1 and C2 can be formed of, for example, an electrical double layer capacitor, an electrical field capacitor, a tantalum capacitor, etc., but are not limited to them.

One of the electrodes of the capacitor (main capacitor, charge accumulation unit) C1 is connected to the node ND, and the other electrode is connected to a ground power supply GND. Further, a predetermined dielectric layer ε1 is inserted between the electrodes of the capacitor C1.

One of the electrodes of the capacitor (auxiliary capacitor, charge accumulation unit) C2 is connected to the node ND via the switch SW1, and the other electrode is connected to the ground power supply GND. Further, a predetermined dielectric layer ε2 is inserted between the electrodes of the capacitor C2.

In the first embodiment, the capacitors C1 and C2 have substantially the same electrical capacitance and substantially the same occupied area on the circuit board 130. For instance, the electrical capacitance of each of the capacitors C1 and C2 is about 200 μF.

[1-2-4. Structures of Tables]

The structures of tables T1 and T2 according to the first embodiment will be described in more detail. As described above, the power supply controller 151 of the first embodiment pre-stores tables T1 and T2.

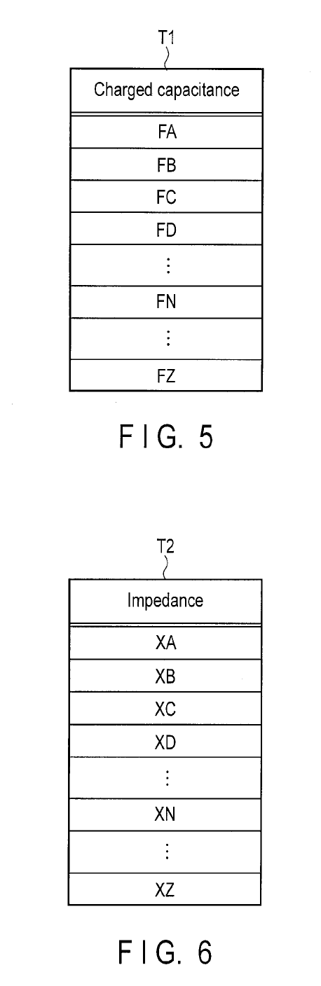

As shown in FIG. 5, table T1 shows a necessary capacitance FN and capacitances (FA, FB, FC, FC, . . . , FZ) measured based on the detection signal PD. The necessary capacitance FN means a capacitance needed for the above-mentioned backup.

As shown in FIG. 6, table T2 shows a reference impedance XN and impedances (XA, XB, XC, XC, . . . , XZ) measured based on the detection signal PD. The reference impedance XN means a limit impedance for the above-mentioned backup (more specifically, it means a certain impedance above which backup processing is impossible).

[2. Power Loss Detection]

Power loss detection performed by the memory system 10 of the first embodiment constructed as the above will be described.

[2-1. Power Loss Detection (upon Power on)]

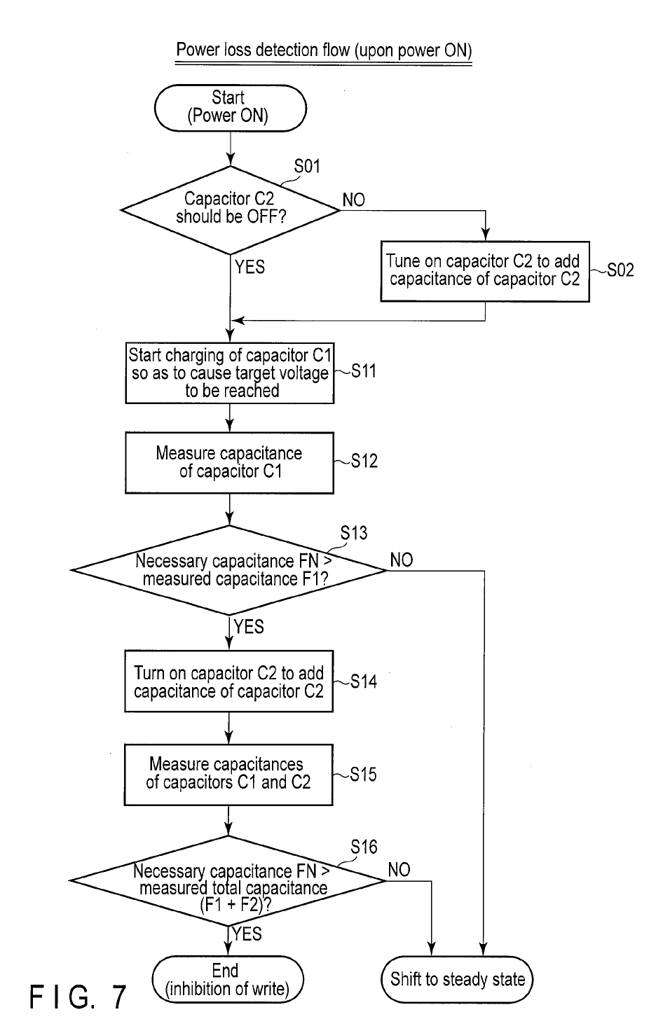

Referring first to the flowchart of FIG. 7, a description will be given of power loss detection performed upon power on.

When the memory controller 15 has detected electrical connection between the memory system 10 and the external power supply VCC (power on), the power loss detection is started.

At this time, in step S01, the memory controller 15 determines whether the auxiliary capacitor C2 should be in the OFF state (whether the capacitor C2 should be electrically disconnected from the node ND).

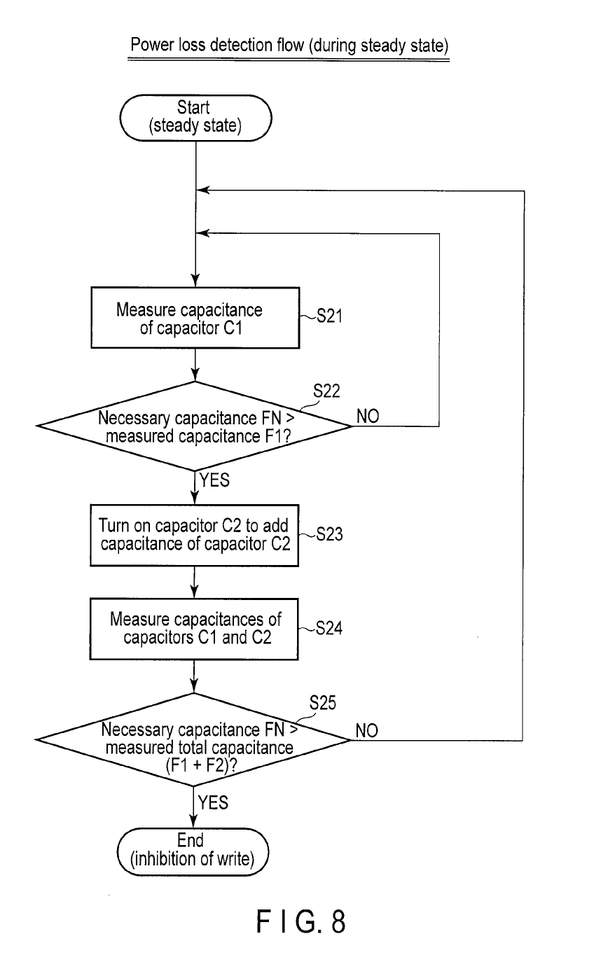

If the memory controller 15 determines that the auxiliary capacitor C2 should be in the ON state (i.e., if the capacitor C2 should be electrically connected to the node ND) (No in step S01), it turns on the auxiliary capacitor C2 and adds the capacitance of the auxiliary capacitor C2 in subsequent step S02. More specifically, in this case, the power supply controller 151 transmits the selection signal SE1 to close the switch SW1, based on the detection signal PD. As a result, the auxiliary capacitor C2 is electrically connected to the charging circuit 113 to start charging, and the charge from the auxiliary capacitor C2 is discharged into the capacitor discharging circuit 114. By this control, such a state (in step S23 in FIG. 8) as a steady state described later, in which the auxiliary capacitor C2 is electrically connected to the node ND, is also maintained at the time of power on.

The above-mentioned steps S01 and S02 are needed when the auxiliary capacitor C2 was previously set in the ON state by power loss detection performed in the steady state described later. The power loss detection in the steady state will be described later.

If it is determined in step S01 that the auxiliary capacitor C2 should be set in the OFF state (i.e., if the capacitor C2 should be electrically disconnected form the node ND (Yes in step S01), and after step S02 is executed, charging of the main capacitor C1 is started to perform control for causing the node ND to reach a predetermined target voltage (set voltage) in step S11. More specifically, the power supply controller 151 controls the capacitor charging circuit 113 to charge the capacitor C1 so as to cause the voltage at the node ND to reach at least the predetermined target voltage.

Subsequently, in step S12, the memory controller 15 measures the capacitance F1 of the main capacitor C1. More specifically, the memory controller 15 measures the capacitance F1 of the main capacitor C1 at the node ND, based on the detection signal PD, utilizing, for example, predetermined voltage conversion.

After that, in step S13, the memory controller 15 determines whether the necessary capacitance FN is greater than the measured capacitance F1 (FN>F1). More specifically, the power supply controller 151 refers to table T1 to compare the necessary capacitance FN with the capacitance F1 measured based on the detection signal PD. If the necessary capacitance FN is smaller than the measured capacitance F1 (FN<F1) (No in step S13), the state is shifted to a steady state described later.

If the memory controller 15 determines that the necessary capacitance FN is greater than the measured capacitance F1 (FN>F1) (Yes in step S13), it turns on the auxiliary capacitor C2 and adds the capacitance of the auxiliary capacitor C2 in step S14. More specifically, in this case, the power supply controller 151 determines, based on the detection signal PD, that the capacitance F1 does not reach the capacitance FN necessary for backup, and transmits the selection signal SE1 to close the switch SW1. As a result, the auxiliary capacitor C2 is electrically connected to the charging circuit 113, whereby charging of the auxiliary capacitor C2 is started, and the capacitance F2 of the auxiliary capacitor C2 is discharged to the node ND.

In step S15, the memory controller 15 measures the capacitances F1 and F2 of the capacitors C1 and C2, respectively. More specifically, the power supply controller 151 measures the total capacitance (F1+F2) of the capacitors C1 and C2, based on the detection signal PD, utilizing, for example, predetermined voltage conversion.

After that, in step S16, the memory controller 15 determines whether the necessary capacitance FN is greater than the measured total capacitance (F1+F2) (FN>F1+F2). More specifically, the power supply controller 151 refers to table T1 to compare the necessary capacitance FN with the total capacitance (F1+F2). If the necessary capacitance FN is smaller than the measured capacitance (F1+F2) (FN<F1+F2) (No in step S16), the state is shifted to the steady state described later.

Lastly, if the necessary capacitance FN is greater than the measured total capacitance (F1+F2) (FN>F1+F2) (Yes in step S16), the memory controller 15 inhibits a data write to the NAND memories 12, followed by the termination of this processing. More specifically, at this time, the memory controller 15 determines that the capacitance FN necessary for backup is not reached, and inhibits any further data write to the NAND memories 12. Even in this case, a predetermined operation (such as a data read from the NAND memories 12) other than a data write can be performed.

[2-2. Power Loss Detection (in Steady State)]

Referring then to the flowchart of FIG. 8, a description will be given of a power loss detection operation in the steady state. The steady state means a state in which the memory system 10 is in the ON state and is performing operations including a data write and other normal operations. The power loss detection operation described below is performed at regular intervals in the steady state.

Firstly, in step S21, the memory controller 15 measures the capacitance F1 of the main capacitor C1. More specifically, the power supply controller 151 measures the capacitance F1 of the main capacitor C1 at the node ND, based on the detection signal PD.

Subsequently, in step S22, the memory controller 15 determines whether the necessary capacitance FN is greater than the measured capacitance F1 (FN>F1). More specifically, the power supply controller 151 refers to table T1 to compare the necessary capacitance FN with the measured capacitance F1 of the main capacitor C1. If the necessary capacitance FN is smaller than the measured capacitance F1 (FN<F1) (No in step S22), the above-mentioned steps S21 and S22 are iterated.

If the necessary capacitance FN is greater than the measured capacitance F1 (FN>F1) (Yes in step S22), the memory controller 15 turns on the auxiliary capacitor C2 to add the capacitance of the auxiliary capacitor C2 in step S23. More specifically, at this time, the power supply controller 151 determines, based on the detection signal PD, that the capacitance F1 does not reach the capacitance FN necessary for backup, and transmits the selection signal SE1 to close the switch SW1. As a result, the auxiliary capacitor C2 is electrically connected to the charging circuit 113, whereby charging of the auxiliary capacitor C2 is started, and the capacitance F2 of the auxiliary capacitor C2 is discharged to the node ND.

In subsequent step S24, the memory controller 15 measures the capacitances F1 and F2 of the capacitors C1 and C2, respectively. More specifically, the power supply controller 151 measures the total capacitance (F1+F2) of the capacitors C1 and C2, based on the detection signal PD.

After that, in step S25, the memory controller 15 determines whether the necessary capacitance FN is greater than the measured total capacitance (F1+F2) (FN>F1+F2). More specifically, the power supply controller 151 refers to table T1 to compare the necessary capacitance FN with the total capacitance (F1+F2). If the necessary capacitance FN is smaller than the measured capacitance (F1+F2) (FN<F1+F2) (No in step S25), the steps S21 et seq. are iterated.

Lastly, if the necessary capacitance FN is greater than the measured total capacitance (F1+F2) (FN>F1+F2) (Yes in step S25), the memory controller 15 inhibits a data write to the NAND memories 12, followed by the termination of this processing. More specifically, at this time, the memory controller 15 determines that the capacitance FN necessary for backup is not reached, and inhibits any further data write to the NAND memories 12. Even in this case, a predetermined operation (such as a data read from the NAND memories 12) other than a data write can be performed.

[2-3. Modification of Power Loss Detection]

The power loss detection described in the above items 2-1 and 2-2 is directed to an example case that seems to be typical with respect to elapse of time. However, the detection is not limited to this.

For instance, if the capacitance of the auxiliary capacitor C2 was added in step S02, charging of the auxiliary capacitor C2 is started in subsequent step S11, as well as the charging of the main capacitor C1. Accordingly, in subsequent step S13, the necessary capacitance FN is compared with the total capacitance (F1+F2).

Further, the object measured based on the detection signal PD is not limited to capacitance. In, for example, step S13, the power supply controller 151 may refer to the above-mentioned table T2, thereby comparing the impedance X1 of the capacitor C1 measured based on the detection signal PD with reference impedance XN. If the reference impedance XN is lower than the measured impedance X1 (XN<X1), control may be performed to add the capacitance of the auxiliary capacitor C2 in subsequent step S14. This is because the impedance of the capacitors will increase due to aging.

Furthermore, the means for determination is not limited to a form of a table, such as table T1 or T2. For instance, a predetermined function, arithmetic formula, etc., may be used for the determination.

[3. Advantageous Effects]

The first embodiment constructed and operating as the above provides at least the following advantageous effects (1):

(1) The life time of the auxiliary power supply circuit 11 can be increased.

The advantageous effects will be described by comparing the first embodiment with a comparative example.

### (A) In the Case of Comparative Example

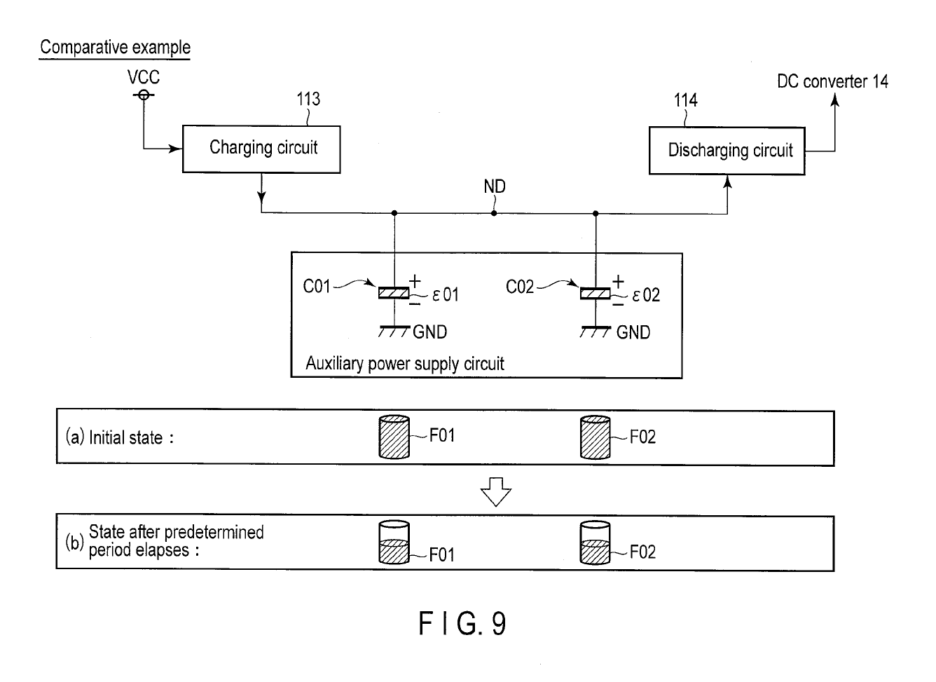

Referring first to FIG. 9, a comparative example will be described.

As shown, an auxiliary power supply circuit as the comparative example merely comprises two capacitors C01 and C02 having large capacitances in order to secure a predetermined capacitance.

The reason why the capacitors C01 and C02 have large capacitances is that the capacitances will greatly decrease depending upon use conditions or age of use. For instance, some capacitors may significantly decrease in capacitance up to 10% or less of the initial capacitance only within a few years. The aging degradation in the capacitances of the capacitors C01 and C02 is caused by degradation of constituents, such as ions in their dielectric layers ε01 and ε02, due to heat. More specifically, the heat includes self-heating due to voltage fluctuation or voltage ripples during charging the capacitors C01 and C02, the heat transferred from the memory controller 15, etc. Because of such heat, the dielectric layers ε01 and ε02 may well be degraded to thereby accelerate the decrease in capacitance or the increase in impedance.

Therefore, in the auxiliary power supply circuit as the comparative example, in order to secure a predetermined life time regardless of aging degradation in capacitance and impedance, it is necessary to secure capacitances greater than the required, i.e., to employ large-capacitance capacitors C01 and C02.

In view of the above, a) the comparative auxiliary power supply circuit holds extra capacitances F01 and F02 more than necessity even in the initial state. This being so, in the comparative auxiliary power supply circuit, charging voltage is continuously applied to all capacitors C01 and C02 from the initial state in which sufficient capacitances are secured.

As a result, b) after a predetermined time elapses, the capacitances and impedances of the capacitors C01 and C02 will substantially simultaneously decrease and increase, respectively, because of the above-mentioned aging degradation.

As described above, in the comparative example, capacitance decrease and impedance increase will occur over time, which is disadvantageous for the increase in life time.

If the areas of the capacitors C01 and C02 are increased to increase the life time of the circuit, the required area of the auxiliary power supply circuit and the manufacturing cost are inevitably increased.

### (B) In the Case of the First Embodiment

The first embodiment will now be described with reference to the above comparative example.

As aforementioned, the auxiliary power supply circuit 11 of the first embodiment comprises the main capacitor circuit 111 that charges and discharges the node ND from the beginning, and the auxiliary capacitor circuit 112 that charges and discharges the node ND when the voltage at the node ND becomes lower than a target voltage (a set value) needed for backup.

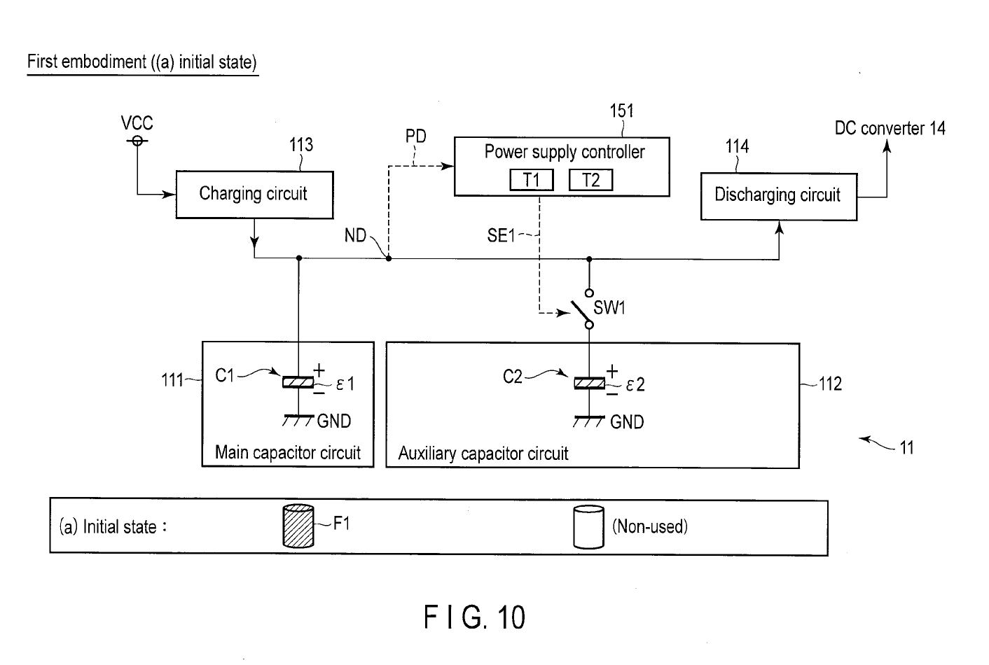

By virtue of this structure, as shown in FIG. 10, a) in the initial state, the auxiliary power supply circuit 11 charges the node ND firstly using only the main capacitor C1 to make the voltage at the node reach a predetermined target voltage necessary for backup (e.g., in step S11 in FIG. 7). Accordingly, in the initial state, the auxiliary capacitor C2 is not used, and hence extra voltage is not applied. As a result, the decrease in the capacitance of the auxiliary capacitor C2 and the increase in the impedance of the same due to aging degradation can be prevented.

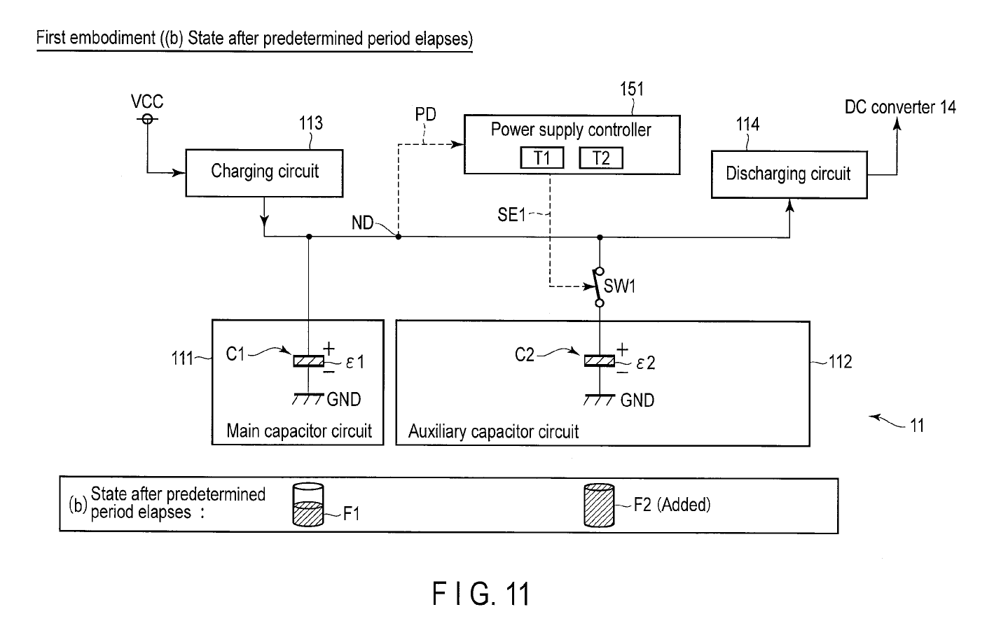

Further, as shown in FIG. 11, b) if the predetermined target voltage necessary for backup is not reached after a predetermined time period elapses, the auxiliary power supply circuit 11 charges the node ND with the capacitance of the auxiliary capacitor C2, using the switch SW1 in the ON state, thereby causing the predetermined target voltage necessary for backup to be reached (in, for example, step S14 in FIG. 7 and in step S23 in FIG. 8). Thus, even when the decrease in the capacitance of the main capacitor C1 has advanced, the predetermined target voltage necessary for backup can be reached by adding the capacitance F2 of the auxiliary capacitor C2 in which the decrease in capacitance is not yet advanced. Therefore, it is advantageous for increasing the life time of the auxiliary power supply circuit 11.

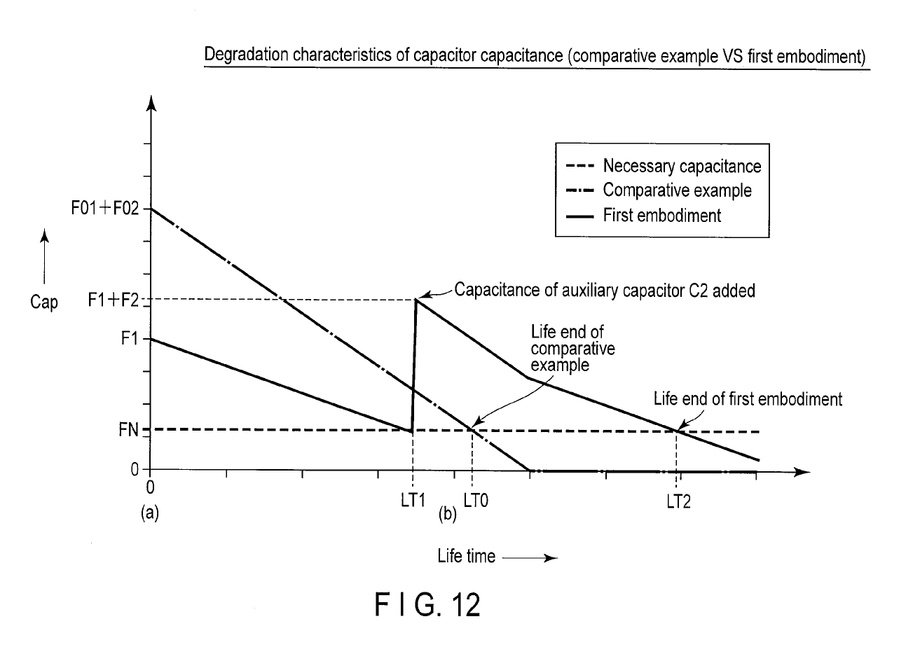

The advantageous effect of the first embodiment is evident from, for example, FIG. 12.

FIG. 12 shows the relationship between the life time and the capacitance in the first embodiment and the comparative example. In the shown case, the capacitances F1 and F2 of the capacitors C01 and C02 according to the first embodiment are both about 200 μF.

As shown, in the comparative example, the capacitance (F01+F02) is significantly greater than the necessary capacitance FN in the initial state. However, at a time LT0, the measured capacitance becomes less than the necessary capacitance FN, which is the life end of the auxiliary power supply circuit.

In contrast, in the first embodiment, the capacitance F1 sufficiently exceeds the necessary capacitance FN in the initial state. At a time LT1, the fact that the capacitance F1 is less than the necessary capacitance FN due to aging degradation is detected, and the capacitance F2 of the auxiliary capacitor C2 is added (F1+F2). As a result, a time LT2, at which the necessary capacitance FN is not reached and the life time of the auxiliary power supply circuit 11 ends, is set much later than the time LT0 in the comparative example. In the example of FIG. 12, it is confirmed that the life time of the device of the first embodiment is increased by about 65% compared to the comparative example.

Further, as described above, in the first embodiment, it is not necessary to increase the areas of the capacitors C1 and C2 in order to increase the life time of the device. This can reduce the area dedicated to the auxiliary power supply circuit 11, and can reduce the manufacturing cost of the device.

### Second Embodiment (Directed to a Reduction Example of a Dedicated Area)

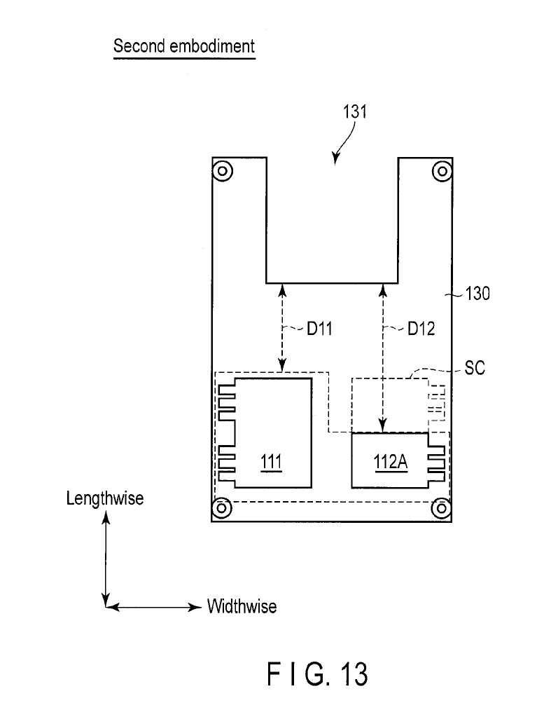

Referring then to FIG. 13, a description will be given of a memory system 10 according to a second embodiment. The second embodiment is directed to a reduction example of an area dedicated to the auxiliary power supply circuit 11. In this embodiment, no detailed description will be given of structural elements and operations similar to those of the first embodiment.

[Auxiliary Power Supply Circuit]

As shown in FIG. 13, an auxiliary power supply circuit 11 according to the second embodiment differs from the first embodiment in that in the former, a dedicated area SC is removed from the circuit board 13 to thereby reduce the dedicated area of an auxiliary capacitor circuit 112A. The dedicated area of the auxiliary capacitor circuit 112A according to the second embodiment can be reduced to, for example, a half the dedicated area of the auxiliary capacitor circuit 112 or the main capacitor circuit 111.

Further, the auxiliary capacitor circuit 112A is provided on the circuit board 130 away from the opening 131 at a distance D12 greater than a distance D11 (D12>D11) along the length of the SSD 10.

Since the other structures and operations are substantially similar to those of the first embodiment, they are not described in detail.

[Advantageous Effects]

As described above, the structures and operations of the second embodiment provide at least the above-mentioned advantageous effects (1). The second embodiment also provides the following advantageous effects (2):

(2) The second embodiment is also advantageous for downsizing.

In the auxiliary power supply circuit 11 of the second embodiment, the dedicated area SC on the circuit board 130 is reduced, and the dedicated area of the auxiliary capacitor circuit 112A is reduced. This is because in the embodiments, the decrease in the capacitance of the auxiliary capacitor circuit 112A due to aging degradation can be suppressed, and hence the predetermined life time of the auxiliary power supply circuit 11 can be guaranteed with a smaller capacitor C2, as described above. Thus, the above structure is advantageous in that it enables the auxiliary power supply circuit 11 to be made compact.

Furthermore, since the number of auxiliary capacitor circuits 112A, the mounting area for them, etc., can be reduced, the number of component parts can be reduced, which results in the reduction of the manufacturing cost.

In addition, the auxiliary capacitor circuit 112A is located on the circuit board 130 away from the opening 131 at the distance D12 greater than the distance D11 (D12>D11) along the length of the SSD 10. This structure can protect the auxiliary capacitor circuit 112A from the heat transferred from the memory controller 15, as described above.

The reduction of the dedicated area is not limited to that of the dedicated area of the auxiliary capacitor circuit 112A. For instance, the dedicated area of the main capacitor circuit 111 can also be reduced. Yet further, both the dedicated areas of the main capacitor circuit 111 and the auxiliary capacitor circuit 112 can be reduced. Thus, the second embodiment is applicable as occasion demands, within a range in which the life time of the auxiliary power supply circuit 11 is guaranteed.

### Third Embodiment (Directed to an Example Case of Employing a Plurality of Auxiliary Capacitors)

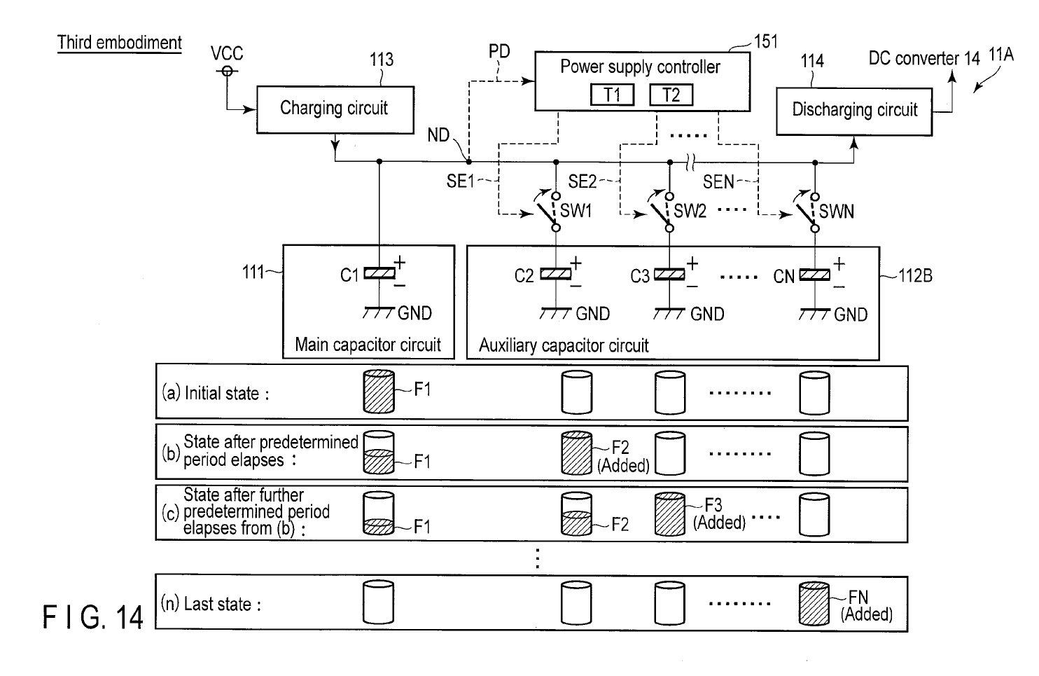

Referring to FIG. 14, a memory system 10 according to a third embodiment will be described. The third embodiment is directed to an example where the auxiliary power supply circuit 11 comprises a plurality of auxiliary capacitors. In the third embodiment, structures and operations similar to those of the first or second embodiment are not described in detail.

[Auxiliary Power Supply Circuit]

As shown in FIG. 14, an auxiliary power supply circuit 11A according to the third embodiment differs from the first and second embodiments in that in the former, an auxiliary capacitor circuit 112B further comprises auxiliary capacitors (C2, C3, . . . , CN).

The third embodiment will be described using an example case where the area for the main capacitor C1 and the plurality of auxiliary capacitors (C2, C3, . . . , CN) are divided into N equal areas. Thus, (N−1) auxiliary capacitors (N is a natural number not less than 3) are employed.

[Power Loss Detection]

In power loss detection according to the third embodiment, if the auxiliary capacitor C2 is kept ON, and if a predetermined target voltage necessary for backup is not yet reached, the auxiliary power supply circuit 11A charges the node ND by sequentially closing switches SW2 to SWN to thereby sequentially add the capacitances of the auxiliary capacitors C3 to CN. As a result, the predetermined target voltage necessary for backup is reached.

Since the other structures and operations are substantially similar to those of the first or second embodiment, they are not described in detail.

[Advantageous Effects]

As described above, the structures and operations of the third embodiment provide at least the above-mentioned advantageous effects (1). The third embodiment also provides the following advantageous effects (3):

(3) The Required Charging Time can be Shortened, and the Consumption of Power can be Reduced.

As shown in FIG. 14, in the third embodiment, a) in the initial state, the auxiliary power supply circuit 11A charges the node ND using only the main capacitor C1, to cause the predetermined target voltage to be reached. Thus, in the initial state, the auxiliary capacitors (C2, C3, . . . , CN) are not used, and hence extra voltage is not applied the auxiliary capacitors (C2, C3, . . . , CN). As a result, the decrease in the capacitances of the auxiliary capacitors (C2, C3, . . . , CN) and the increase in the impedances of them due to aging degradation can be suppressed, and further the charging time of the main capacitor C1, which has a small area, can be shortened. As a result, the charging time can be shortened and the consumption of power can be reduced. For instance, in the third embodiment, in the initial state, if the main capacitor C1 is charged utilizing a constant current charging method, the charging time can be shorted to 1/Nth the charging time of the comparative example.

Subsequently, as shown in FIG. 14, b) if the predetermined target voltage needed for backup is not reached even after a predetermined time elapses, the auxiliary power supply circuit 11A charges the node ND by adding the capacitance of the auxiliary capacitor C2 through the switch SW1 in the ON state, thereby causing the predetermined target voltage necessary for backup to be reached. Thus, even when the decrease in the capacitance of the main capacitor C1 has advanced, the predetermined target voltage necessary for backup can be reached by adding the capacitance F2 of the auxiliary capacitor C2 in which the decrease in capacitance is not yet advanced. Further, in the third embodiment, since the area of the auxiliary capacitor C2 added is small, the charging time of the capacitor can be shortened and the consumption of power can be reduced.

After that, as shown in FIG. 14, c) if the predetermined target voltage needed for backup is not reached even after a predetermined time elapses from b) the above-mentioned time, the auxiliary power supply circuit 11A charges the node ND by further adding the capacitance of the auxiliary capacitor C3 through the switch SW2 in the ON state, so as to cause the predetermined target voltage necessary for backup to be reached. Also in this state, the area of the auxiliary capacitors C2 and C3 added is small, and hence the charging time of the capacitor can be shortened and the consumption of power can be reduced.

The above-described operation is iterated. n) If in the last state, the predetermined target voltage needed for backup is not reached, the auxiliary power supply circuit 11A charges the node ND by further adding the capacitance of the auxiliary capacitor CN through the switch SWN in the ON state, so as to cause the predetermined target voltage necessary for backup to be reached.

In addition to the above advantageous effects, the third embodiment is also advantageous in that the shortening of the charging time enables the time required for activation of the SSD 10 to be shortened.

As shown in, for example, FIG. 7, the activation of the SSD 10 is completed after the capacitor C1 and/or capacitors C2 to CN are charged. In the third embodiment, since the area for the capacitor C1 and/or capacitors C2 to CN is small, the charging time can be shortened as mentioned above. The shortening of the charging time enables the time required for activation of the SSD 10 to be shortened.

Although the third embodiment is directed to an example case where the area for the main capacitor C1 and the plurality of auxiliary capacitors (C2, C3, . . . , CN) are divided into N equal areas, third embodiment is not limited to this structure. For instance, the area of the main capacitor C1 may be greater than the area of each auxiliary capacitor (C2, C3, . . . , CN). Thus, the area of each capacitor can be varied as the occasion arises.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory;
a memory controller which controls the nonvolatile memory; and
an auxiliary power supply circuit which applies an auxiliary voltage for performing backup to the nonvolatile memory and the memory controller,
wherein the auxiliary power supply circuit includes:
a first capacitor circuit which applies the auxiliary voltage; and
a second capacitor circuit which adds a further voltage to the auxiliary voltage when the auxiliary voltage applied by the first capacitor circuit is less than a voltage needed for the backup.

2. The memory system of claim 1, further comprising a power supply controller which receives, from the auxiliary power supply circuit, a detection signal indicative of whether the auxiliary voltage is less than the voltage needed for the backup.

3. The memory system of claim 2, wherein the power supply controller controls the second capacitor circuit to add the further voltage to the auxiliary voltage, based on the received detection signal.

4. The memory system of claim 2, further comprising a switch which causes the second capacitor circuit to be conductive under control of the power supply controller when the auxiliary voltage is less than the voltage needed for the backup.

5. The memory system of claim 1, wherein
the first capacitor circuit includes a first capacitor which applies the auxiliary voltage; and
the second capacitor circuit includes a second capacitor which adds the further voltage to the auxiliary voltage.

6. The memory system of claim 1, further comprising:
a first exterior member covering the memory controller; and
a second exterior member covering the first and second capacitor circuits and different from the first exterior member.

7. The memory system of claim 1, wherein the memory controller is provided on a board at a predetermined distance from the first and second capacitor circuits.

8. The memory system of claim 1, further comprising a charging circuit which charges the first and second capacitor circuits with a power supply voltage from an external power supply.

9. The memory system of claim 1, further comprising a converter which converts the auxiliary voltage from the auxiliary power supply circuit into a predetermined voltage, and applies the predetermined voltage as an internal power supply voltage to the nonvolatile memory and the memory controller.

10. The memory system of claim 9, further comprising a discharging circuit which discharges voltages from the first and second capacitor circuits to the converter.

11. The memory system of claim 2, further comprising a first table showing a necessary capacitance needed for performing the backup, and a capacitance measured based on the detection signal,
wherein the power supply controller refers to the first table to compare the necessary capacitance with the capacitance measured based on the detection signal, and controls the second capacitor circuit to add the further voltage to the auxiliary voltage, based on a result of the comparison.

12. The memory system of claim 2, further comprising a second table showing a reference impedance to be referred to for performing the backup, and an impedance measured based on the detection signal,
wherein the power supply controller refers to the second table to compare the reference impedance with the impedance measured based on the detection signal, and controls the second capacitor circuit to add the further voltage to the auxiliary voltage, based on a result of the comparison.

13. The memory system of claim 1, wherein an area of the second capacitor circuit on a board is smaller than an area of the first capacitor circuit on the board.

14. The memory system of claim 5, wherein
the second capacitor circuit includes a plurality of second capacitors; and
the first capacitor and the plurality of second capacitors have equal areas.

15. A storage system that uses the memory system of claim 1.

16. The storage system of claim 15, wherein the memory system further comprises a power supply controller which receives, from the auxiliary power supply circuit, a detection signal indicative of whether the auxiliary voltage is less than the voltage needed for the backup.

17. The storage system of claim 16, wherein the power supply controller controls the second capacitor circuit to add a further voltage to the auxiliary voltage, based on the received detection signal.

18. The storage system of claim 16, wherein the memory system further comprises a switch which causes the second capacitor circuit to be conductive under control of the power supply controller when the auxiliary voltage is less than the voltage needed for the backup.

19. The storage system of claim 15, wherein
the first capacitor circuit includes a first capacitor which applies the auxiliary voltage; and
the second capacitor circuit includes a second capacitor which adds the further voltage to the auxiliary voltage.

20. A memory system comprising a power supply circuit,
the power supply circuit including:
a first capacitor circuit which applies a voltage to a nonvolatile memory and a memory controller; and
a second capacitor circuit which adds a further voltage to the voltage applied by the first capacitor circuit, when the voltage applied by the first capacitor circuit is less than a set value.
